(19) United States
(12) Patent Application Publication
(10) Pub. No.: US 2011/0017293 A1
(43) Pub. Date: Jan. 27, 2011

(54) Thin film photovoltaic module having a lamination layer for enhanced reflection and photovoltaic output

(76) Inventors: James F. Farrell, Toronto (CA); Satyanarayana Rao Peddada, San Jose, CA (US)

Correspondence Address: WOODSIDE IP GROUP, P.O. BOX 61047, PALO ALTO, CA, 94306, US

(21) Appl. No.: 12/584,079

(22) Filed: Aug. 31, 2009

Related U.S. Application Data
(60) Provisional application No. 61/271,775, filed on Jul. 24, 2009.

(51) Int. Cl. H01L 31/18; H01L 31/00

(52) U.S. Cl. 136/259; 438/72; 257/E31.127

(57) ABSTRACT

An improved thin film PV module and simplified fabrication process are provided that achieve higher PV module efficiency, while eliminating expensive process steps, and reducing the capital cost of thin film processing equipment. A lamination material, characterized by high reflectivity as well as thermal conductivity and emissivity, is provided directly adjacent the active region of a thin film stack, eliminating the need for complex sputtering or deposition process steps ordinarily required for providing a reflective layer. The lamination material reflects unabsorbed light back into the thin film stack, thereby increasing photocurrent generation, and obviating the need for a reflective metallization layer. The lamination layer and back sheet for sealing the light-absorbing stack against the ingress of moisture also can be applied in a single process step.

### CROSS REFERENCE TO RELATED APPLICATION

This application claims the benefit of U.S. provisional patent application Ser. No. 61/271,775, filed Jul. 24, 2009.

### BACKGROUND

1. Field of the Invention

The field of the invention generally relates to photovoltaic (PV) modules. In particular, the field of the invention relates to an easily manufactured thin film PV module comprising a lamination sheet characterized by high reflectance for reflecting the unabsorbed solar radiation back into the thin film stack, resulting in enhanced photo current generation, and for simplifying the semiconductor process steps for the thin film stack.

2. Background of Related Art

As is well known, in a thin film photovoltaic solar cell, solar radiation is absorbed by the active thin film layer of semiconductor material resulting in generation of electrons and holes. The electrons and holes are separated by a built-in electric field, such as a rectifying junction, as in a conventional solar cell. The separation of electrons and holes across the built-in electric field results in the generation of photocurrent of the cell. Thin film solar cells have advantages over conventional solar cells in terms of lower material costs, simplified structure, and ease of manufacture.

Thin film solar cells utilize a higher proportion of their surface area as an active region for generating photocurrent in comparison to a crystalline silicon solar cell. In a crystalline silicon PV module, each solar cell is formed on a separate crystalline silicon substrate. Linking conventional solar cells together into a PV module results in gaps between cells. Also, valuable surface area must be provided for wiring solar cells to a connection means such as a junction box. Thus, the area of an active region for converting sunlight to electric power is about 70 to 80 percent of the entire surface area of a conventional crystalline silicon based PV module.

In contrast, in a thin film PV module, solar cell elements are formed directly on a transparent insulating substrate and are integrated or electrically connected on the substrate. In such a substrate integration thin film PV module, the area of the active region for electric power generation can be increased to more than 90 percent of the entire surface area occupied by the PV module. Therefore, what is also needed is a way to utilize the relatively greater surface area of the active region in a thin film PV module for increased photocurrent output.

Compared to conventional crystalline silicon solar cells, thin-film solar cells exhibit less efficiency for converting sunlight to usable electric power. Therefore, what is needed is a means to increase as much as possible the absorption of solar radiation by the active region of the thin film stack. This advantageously would increase photocurrent generation and reduce the gap in conversion efficiency between conventional crystalline silicon solar cells and thin-film solar cells.

A conventional thin film PV module comprises a thin film metal reflecting layer or a printed layer of white ink or paint applied behind the thin film stack to reflect unabsorbed light back into the thin film stack. The lamination material is usually polyvinyl butyral (PVB) a plastic layer used between glass pieces in the laminating process. Alternatively, ethylene vinyl acetate, also known as EVA, may be used. Such lamination materials are optically clear, and provide no reflectance. In such a conventional thin film PV module, providing reflectance to the back of the thin film stack is complex and expensive, since it requires extra deposition process steps, adds process time, and requires significant capital expenditure for processing equipment.

A disadvantage in the construction of a conventional thin film PV module is that the lamination materials are not filled and are not thermally conductive. Conventional thin film lamination materials tend to be thermally insulative, and thereby cause undesirable retention of heat upon prolonged exposure to the sun.

Accordingly, in high intensity sunlight, conventional thin film photovoltaic solar cells become very hot due to the absorption of sunlight and its conversion to heat. The thin film PV cells are sandwiched inside the module and the typical lamination layer thermally insulates the thin film cells from the outside ambient temperature. Since there is no way for heat to escape, conventional thin film PV cells exhibit reduced efficiency as their temperature increases.

### SUMMARY

The aspects and features of the invention address current deficiencies and provide solutions that may be critical for developing low-cost and reliable thin film PV modules:

(a) reduced photovoltaic active layer stack process steps, and thus the potential to standardize equipment for the deposition or growth of the light absorbing thin films;

(b) simplified prevention of moisture ingress, thereby eliminating complex, expensive process steps, and reducing the capital cost of processing equipment;

(c) higher thin film PV module efficiency.

An aspect of the invention increases the photocurrent of the active layer of a thin film stack by integrating highly reflective, thermally conductive particles with a lamination material used to adhere the back sheet to the front sheet of a PV module. In a thin film application, the transparent front substrate or sheet of the module contains the photovoltaic thin film stack. Light passing through the thin film stack on the front sheet generates a photocurrent. Some of the incident light is not absorbed in the thin film stack and passes through the active layer into the lamination material. Since the lamination material is integrated with highly reflective particles characterized by a diameter on the order of 0.2 microns, the reflection mechanism is by Mie scattering that both scatters and provides diffuse reflectance. Thus, the lamination material is highly reflective to a broad range of solar radiation, reflecting substantially all unabsorbed light passing through the thin film stack back into the active layer, thereby generating additional photocurrent.

This aspect of the invention advantageously eliminates the need for a paint layer or reflective metal layer to be applied by deposition or sputtering to the thin film stack, and reduces semiconductor processing steps required for forming the thin film stack. Such simplified semiconductor processing can lead to standardized equipment, and potentially can eliminate undesirable variability and defects in the light absorbing layers and enhance the potential for wide area VLSI deposition of the thin film stack. The application of a reflective lamination layer directly to the thin film stack also provides a simplified, cost effective means for preventing moisture ingress into the thin film stack, thus obviating a major cause of component failure. In a further aspect of the invention, the lamination material improves the thermal conductivity by providing a low resistance path for thermal dissipation from the interior of the PV module directly to the outside ambient surroundings, thereby making the module cooler, and thus more efficient in high sunlight conditions. Providing the lamination material directly on the light absorbing film obviates thermal expansion coefficient mismatches between the light absorbing layer and the reflective layer, thereby enhancing PV module reliability over extended cycles of heating and cooling.

### BRIEF DESCRIPTION OF THE DRAWINGS

The drawings are heuristic for clarity. The foregoing and other features, aspects and advantages of the invention will become better understood with regard to the following description, appended claims and accompanying drawings in which:

FIG. 1 is a side sectional view of a conventional thin film PV module comprising a thin film stack.

FIG. 2 is a simplified process diagram for making the conventional thin film PV module of FIG. 1.

FIG. 3 is a side sectional view of a thin film PV module with a highly reflective and thermally conductive lamination material in accordance with an aspect of the invention.

FIG. 4 is a process diagram for making the thin film PV module of FIG. 3 in accordance with an aspect of the invention.

FIG. 5 is a graph showing how optimal particle size may be selected for a lamination pigment to achieve the highest reflection with respect to various wavelengths of light.

### DESCRIPTION OF THE PREFERRED EMBODIMENTS

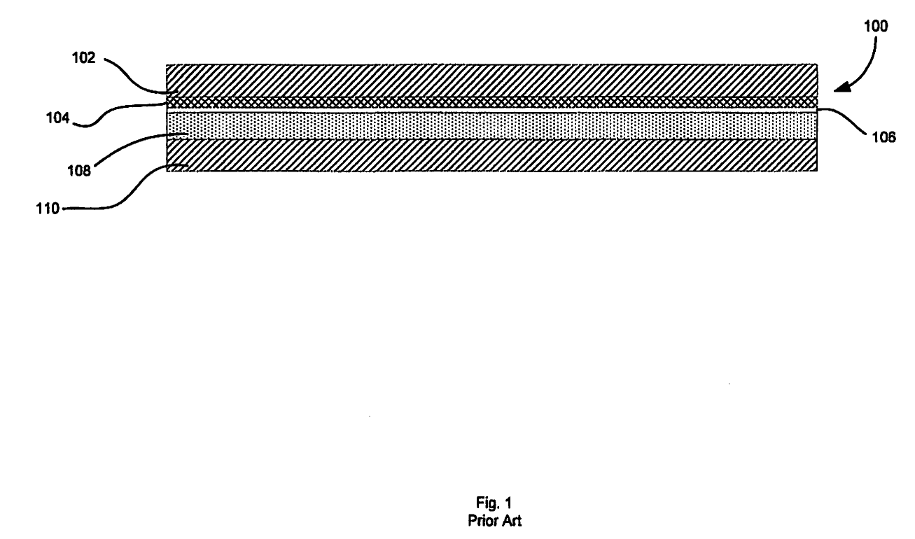

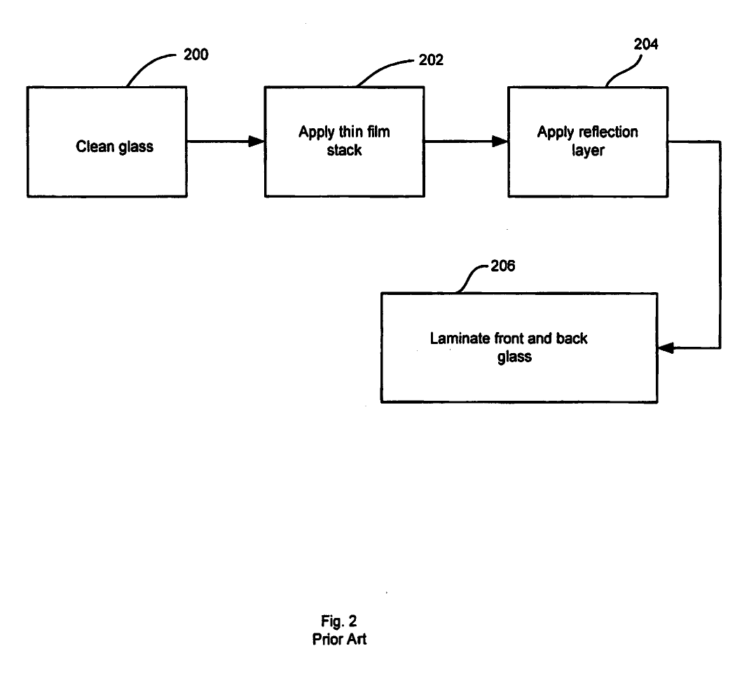

Referring to the drawings, FIGS. 1 and 2 show a cross section of a conventional thin film PV module 100 and a standard process for making the PV module, respectively. The thin film PV module comprises a transparent substrate 102 such as glass. A light absorbing thin film stack 104 is provided on the interior side of transparent substrate 102 using multiple semiconductor processing steps. An example of a conventional process for forming a light absorbing thin film stack is shown in Schicht et al., U.S. Pat. No. 6,159,621 incorporated herein by reference. The thin film stack 104 can be formed by any well known thin-film PV technology including epitaxial Si, copper indium gallium deselenide (CIGS), cadmium telluride (CdTe), or the like.

Referring to FIG. 1 and the process in FIG. 2, transparent substrate 102 typically comprises a transparent substrate such as glass that is carefully cleaned as shown at 202 prior to the application of the light-absorbing thin film stack 104. A thin film reflecting layer 106 is applied over and behind the thin film stack 104 to reflect unabsorbed light back into the thin film stack as shown at 206. The reflective layer 106 typically is a sputtered thin film layer of reflective metal, or a printed layer of white ink or paint.

A film stack that includes a reflective metal layer such as silver or other highly reflective metal film is relatively costly to manufacture, since such a reflective layer can be produced only at a relatively low sputtering rate. Moreover, film materials must be wetted optimally at their interfaces so that they propagate as coherent films without forming islands and must adhere well to one another. To apply such a reflective metal layer over a thin film stack in a continuous-feed system requires an extra sputtering station, or additional equipment for providing a reflective film such as ink or paint. A lamination material 108, such as polyvinyl butyral (PVB), ethylene vinyl acetate (EVA) or plastic layer is then used to laminate the front glass 102 and the integrated thin film stack to the back glass 110 in a standard lamination process at 210.

In such a conventional thin film PV module, providing reflectance to the back of the thin film stack disadvantageously requires extra process steps for the light absorbing stack, adds process time, and may require significant capital expenditure for additional processing equipment. Over time, extended cooling and heating cycles may weaken or degrade the light absorbing film due to thermal expansion coefficient mismatches between the reflective layer and the active layers.

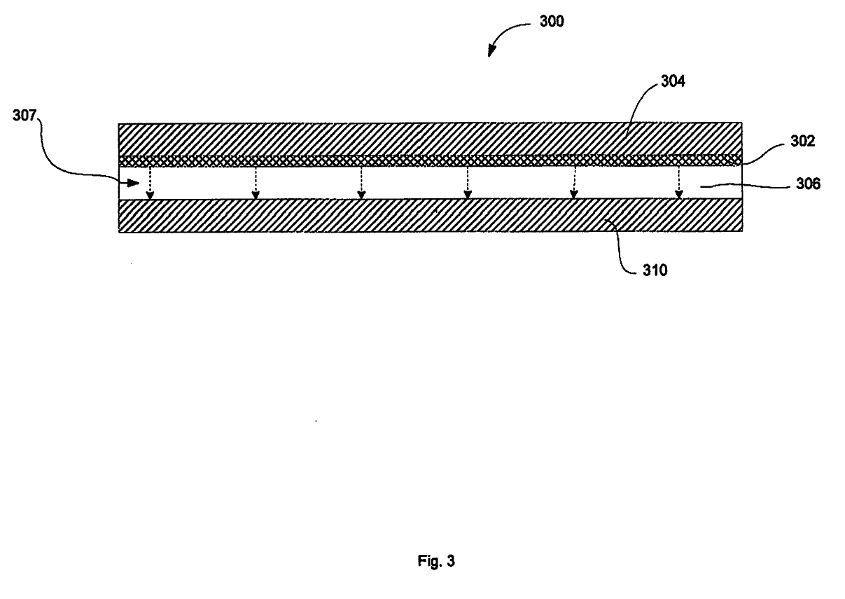

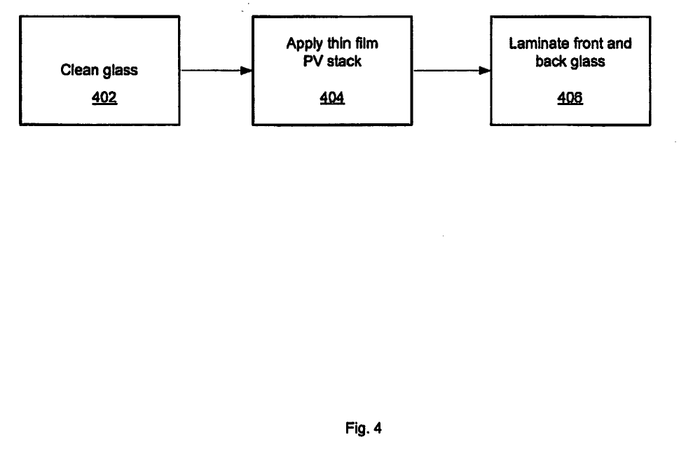

Referring to FIGS. 3 and 4, an aspect of the invention provides a simplified, low cost thin film PV module 300, and process for producing such a thin film PV cell, that enables improvements in both thin film productivity and PV module efficiency. A light-absorbing thin film stack 302 is provided according to well-known techniques on a cleaned, transparent substrate such as glass 304. A lamination material 306 is provided directly adjacent the light absorbing thin film stack 302 and standard lamination techniques are used adhere the back sheet 310 to the lamination material 306 such that the lamination material 306 seals light absorbing stack 302 directly between the front glass 304 and back sheet 310, thereby providing a cost effective means for preventing moisture ingress to the thin film stack.

Lamination material 306 improves the thermal conductivity by providing a path 307 for thermal transfer and dissipation from the interior of the PV module 300 to the back sheet glass 310, which is in contact with the outside ambient, making the module cooler and thus more efficient in high sunlight conditions. Providing the lamination material 306 directly on the light absorbing film 302 also advantageously obviates thermal expansion coefficient mismatches between the light absorbing layer and the reflective layer, thereby enhancing PV module reliability over extended cycles of heating and cooling.

In accordance with an aspect of the invention, the lamination material 306 is characterized by high reflectivity as well as thermal conductivity and emissivity, and advantageously eliminates the need for a reflective metallization layer in the thin film stack. The lamination material is applied by any convenient transparent adhesive to the adjacent surface of thin film stack 302, eliminating the need for complex sputtering or deposition process steps required for providing a reflective layer.

Lamination material 306 reflects unabsorbed light by the mechanism of Mie scattering back into the adjacent thin film stack 302 so that more photocurrent is generated. The lamination material comprises a composite material such as: polyvinyl butyral (PVB), ethylene vinyl acetate (EVA), thermoplastic polymer, thermoplastic copolymer, plastic, or like material loaded with powder or particles of white pigment characterized by a reflectance value of about 90 percent or greater with respect to solar radiation in a range of about 400 nm to above 900 nm.

The mechanism of reflection of the particles is Mie scattering. This is characterized by a diffuse reflectance that both scatters and reflects light. Mie scattering is achieved by the small size, approx. 0.2 microns in diameter, of the reflective particles. The Mie scattering mechanism advantageously captures and reflects back substantially all unabsorbed light passing through the active light absorbing surface of the thin film stack.

In a non-limiting example of a preferred embodiment, lamination material 306 comprises a thermoplastic polymer or the like that is loaded with a white pigment characterized by a reflectance value of greater than 95 percent. One example of such a pigment is titanium dioxide TiO2 powder. Such a TiO2 loaded polymer film is capable of reflecting (with a reflectance value of 95 percent or higher) substantially all incident solar radiation in a range of about 400 nm to above 900 nm. The reflective white pigment may be loaded as a composite, mixture or matrix within the laminate material, or may be provided in a first surface of the laminate by any well known, convenient means. When unabsorbed sunlight from the thin film stack 302 passes through the light absorbing thin film stack to the white pigmented lamination layer 306, substantially all of this otherwise unutilized light is captured by the white pigment and reflected back into the light-absorbing stack 302. The reflection mechanism is Mie scattering. This advantageously results in higher photocurrent being generated by the thin film stack.

Titania is chosen as a preferred white pigment material due to its high refractive index, low porosity, and relatively high thermal conductivity, which is much higher than the unloaded lamination polymer. The most important function of titanium dioxide, however, is its incorporation in powder form as a pigment for providing whiteness and opacity to products such as paints and coatings (including glazes and enamels), plastics, paper, inks, fibers, or the like.

Titanium dioxide is by far the most widely used white pigment. Titania is very white and has a very high refractive index—surpassed only by diamond. The refractive index determines the opacity that the material confers to the matrix in which the pigment is housed. Thus, with its high refractive index, relatively low levels of titania pigment are required to achieve a white opaque coating. Titanium dioxide material is used as an opacifier in glass and porcelain enamels, cosmetics, sunscreens, paper, and paints. One of the major advantages of the material for exposed applications is its resistance to discoloration under UV light. Thus, the high refractive index and bright white color of titanium dioxide make it an effective opacifier for pigment provided on or incorporated in the lamination layer 306.

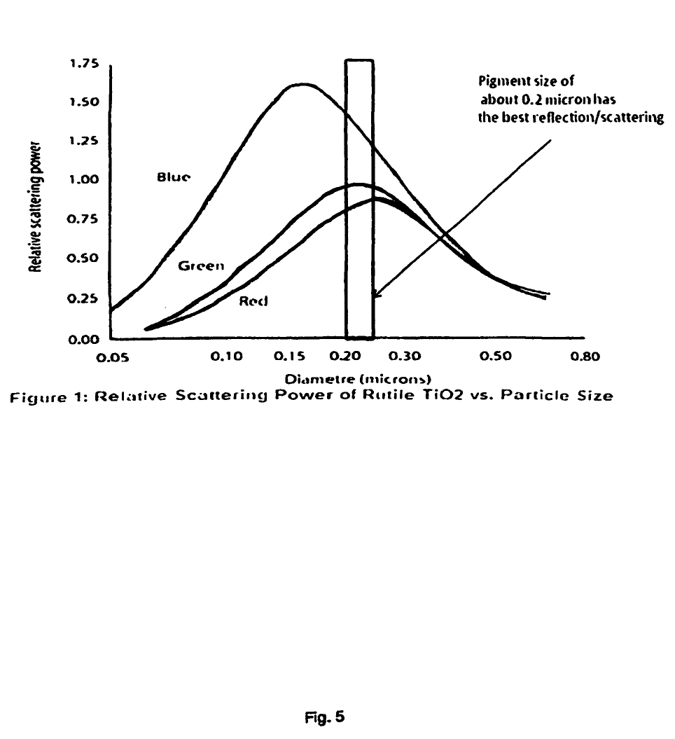

Referring to FIG. 5, the reflectivity and scattering of Titania pigment in a matrix is a function of particle size, and therefore the optimum particle size must be selected. The Mie solution to Maxwell's equations is used to calculate the particle size best suited to scatter and reflect visible light. The rectangle in FIG. 5 shows an optimal range of particle size with respect to a particle's ability to reflect solar radiation in blue, green and red wavelengths. As shown, a pigment particle having a diameter on the order of 0.2 microns achieves the best overall reflection and light scattering.

Referring again to FIG. 3, the thermal conductivity of a titania, such as TiO2 is 11.7 W/mK at 25 degrees C., whereas the unloaded PVB has a thermal conductivity in the range of 0.5 W/mK. In an aspect of the invention, the laminate or lamination material 306 is a composite, that is, a PVB, EVA, thermoplastic polymer, thermoplastic copolymer or plastic, loaded with a white pigment or integrated with a matrix of highly thermally conductive particles, such as titania. The laminate including the matrix of thermally conductive/reflective particles thus provides a low resistance thermal path from the light absorbing surface directly to the back sheet of the PV module. The high thermal conductivity of the titania sets up a temperature gradient along the interface between the lamination material 306 and light-absorbing stack 302. The temperature gradient extends from the relatively hot interior to the cooler exterior back sheet of the PV module 300. The temperature gradient thus defines a thermal path 307 extending from the front sheet, or the light absorbing thin film stack 302 directly to the shaded exterior or back sheet of the PV module. The thermally conductive path 307 provides for preferential conduction and transfer of heat built up within the PV module to the outside ambient surroundings, where heat is dissipated, resulting in cooling of the PV module and greater photo conversion efficiency in high temperature conditions.

In accordance with basic empirical techniques that are well known, the density of titania or other thermally conductive particles provided in the laminate material may be varied to a level sufficient to substantially increase thermal conductivity of the laminate, such that a low resistance thermal path is provided for conducting heat directly from the front sheet to the back sheet of the PV module. A particle density in a range of 15-25 percent by weight and most preferably about 20 percent by weight achieves an optimal reflectance of incident light A density of particles in a range of at least about 20 percent is sufficient to substantially increase the thermal conductivity of the laminate such that a low resistance thermal path is established directly between the front sheet and the shaded back sheet of the PV module.

In addition to making the polymer lamination material highly reflective, the white pigment also increases the thermal conductivity of the lamination sheet and reduces its thermal expansion coefficient. The reduced thermal expansion coefficient results in reduced stress on the active layers of the PV module.

The increased thermal conduction of the lamination material provides for a lower resistance thermal path, 307, to the back sheet glass and to the outside ambient temperature than would normally be provided by the unloaded polymer lamination in a conventional thin film PV module laminated with clear polymer.

Relevant properties of Titania are listed in the following tables.

TABLE 1
Typical physical and mechanical properties of Titania

| Density | 4 | gcm⁻³ |
|---|---|---|
| Porosity | 0% | |
| Modulus of Elasticity | 230 | GPa |
| Microhardness (HV0.5) | 880 | |
| Resistivity (25° C.) | 10¹² | ohm · cm |
| Resistivity (700° C.) | 2.5 × 10⁴ | ohm · cm |
| Dielectric Constant (1 MHz) | 85 | |
| Dissipation factor (1 MHz) | 5 × 10⁻⁴ | |
| Dielectric strength | 4 | kVmm⁻¹ |
| Thermal expansion (RT-1000° C.) | 9 × 10⁻⁶ | |
| Thermal Conductivity (25° C.) | 11.7 | WmK⁻¹ |

TABLE 2
Optical Properties of Titania.

| | Refractive | Density | Crystal |
|---|---|---|---|
| Phase | Index | (g · cm⁻³) | Structure |
| Anatase | 2.49 | 3.84 | Tetragonal |
| Rutile | 2.903 | 4.26 | Tetragonal |

Referring to FIG. 3 and FIG. 4, lamination layer 306 enables a simplified process to be provided for constructing a thin film PV module. The lamination layer and back sheet can be applied in a single process step. A transparent substrate such as glass 402 is cleaned in preparation for semiconductor processing of the thin film stack. A thin film stack is applied to the cleaned substrate at 404, and the laminate material is simply adhered to the completed thin film stack and the back glass or other protective back sheet in a single step at 406.

Since the lamination material itself is highly reflective, this eliminates the need for a paint layer or reflective metal layer to be applied separately to the thin film stack. The lamination material also seals the light-absorbing stack 302 against the ingress of moisture. Thus, the complex and time consuming deposition process for forming the thin film light-absorbing stack and protecting the light-absorbing stack against ingress of moisture advantageously can be simplified. This aspect of the invention may facilitate large scale thin-film PV module manufacturing that can lower the unit cost of module production.

While the invention has been described in connection with what are presently considered to be the most practical and preferred embodiments, it is to be understood that the invention is not limited to the disclosed embodiments, but rather is intended to cover various modifications and equivalent arrangements within the scope of the following claims. For example, other highly reflective substances such as BaSO4 may be substituted for titania particles. However, in such a structure the reflection mechanism still would be achieved by Mie scattering, and the reflective and thermally conductive properties would be substantially equivalent to the present PV module. Therefore, persons of ordinary skill in this field are to understand that all such equivalent arrangements are to be included within the scope of the following claims.

We claim:

1. A thin film PV module comprising:
a light-absorbing thin film stack having an exposed surface and a light-absorbing surface provided on a transparent front sheet;
a back sheet;
a laminate, provided directly on the exposed surface of the thin film stack, characterized by high reflectivity and thermal emissivity for sealing the front sheet to the back sheet, such that the thin film stack is sealed between the front sheet and the back sheet.

2. A thin film PV module as in claim 1, wherein the laminate further comprises a material selected from the group consisting of: polyvinyl butyral (PVB), ethylene vinyl acetate (EVA), thermoplastic polymer, thermoplastic copolymer or plastic, loaded with a white pigment characterized by a reflectance value of about 90 percent or greater with respect to solar radiation in a range of about 400 nm to above 900 nm.

3. A thin film PV module as in claim 2, wherein the white pigment comprises titania or like particles.

4. A thin film PV module as in claim 2, wherein the white pigment comprises particles of titania or the like characterized by a diameter on the order of 0.2 microns.

5. A thin film PV module as in claim 4, wherein the particles are provided in the laminate material in a density sufficient to substantially increase thermal conductivity of the laminate, such that a low resistance thermal path is provided for conducting heat directly from the front sheet to the back sheet.

6. A thin film PV module comprising:
a light-absorbing thin film stack having a light absorbing surface provided on a light incident surface of a transparent substrate;
a back sheet;
a reflective lamination material provided directly adjacent the light absorbing thin film stack for adhering the back sheet thereto, and for reflecting unabsorbed light passing through the light-absorbing surface back into the thin film stack.

7. A thin film PV module as in claim 6 wherein the lamination material comprises a material chosen from the group consisting of: polyvinyl butyral (PVB), ethylene vinyl acetate (EVA), thermoplastic polymer, thermoplastic copolymer or plastic; and integrated with white pigment particles, such as titania,

8. A thin film PV module as in claim 7 wherein the lamination material comprises a composite wherein white pigment particles comprise 15-25 percent by weight

9. A thin film PV module as in claim 8 wherein the particles further comprise titanium dioxide, TiO2, particles characterized by a diameter on the order of 0.2 microns.

10. A thin film PV module as in claim 9 wherein the titanium dioxide particles are characterized by a density in a range of 15-25 percent by weight and most preferably on the order of 20 percent by weight.

11. A method for making a thin film PV module comprising the steps of providing a light-absorbing thin film stack including a light-absorbing surface on a transparent front sheet;
adhering a reflective lamination layer comprising a reflective surface and a back sheet directly to the thin film stack such that the reflective surface is adjacent the thin film stack for reflecting unabsorbed light back into the light absorbing surface, and the back sheet seals the thin film stack from ingress of moisture.

12. A method for making a thin film PV module comprising the steps of:
providing a thin film stack having an active region on a transparent substrate;
providing a laminate comprising a back sheet and a matrix of particles characterized by a Mie reflectance value of greater than 90 percent with respect to incident solar radiation in a range of about 400 nm to above 900 nm;
adhering the laminate to an exposed surface of the thin film stack such that the back sheet seals the thin film stack and front sheet against ingress of moisture.

13. A method for making a thin film PV module as in claim 12, wherein the step of providing a laminate further comprises the steps of:
providing a lamination material chosen from a group consisting of polyvinyl butyral (PVB), ethylene vinyl acetate (EVA), thermoplastic polymer, thermoplastic copolymer or plastic;
incorporating white pigment particles, such as titania, having a diameter on the order of 0.2 microns, into the lamination material;
providing a moisture proof back sheet on a back surface of the lamination material.

14. A method for making a thin film PV module as in claim 13, wherein the step of incorporating white pigment particles into the lamination material further comprises incorporating particles characterized by at least 20 percent by weight to increase thermal conduction of the lamination material, such that a low resistance thermal path is provided for dissipating heat directly from the front sheet to the back sheet.
